(19) United States
(12) Patent Application Publication
(10) Pub. No.: US 2018/0358495 A1
(43) Pub. Date: Dec. 13, 2018

(54) DIELECTRIC COATING FORMULATION FOR METAL INTEGRATED SOLAR PANEL

(71) Applicants: TATA POWER SOLAR SYSTEMS LIMITED, Bangalore (IN); TATA STEEL LIMITED, Jamshedpur (IN)

(72) Inventors: Arul SHANMUGASUNDRAM, Bangalore (IN); Tapan Kumar ROUT, Odisha (IN); Mukundan NARASIMHAN, Bangalore (IN); Prosenjit BOSE, Bangalore (IN); Amresh MAHAJAN, Bangalore (IN)

(21) Appl. No.: 15/562,338

(22) PCT Filed: Mar. 24, 2016
(86) PCT No.: PCT/IB16/51669

§ 371 Date: Sep. 27, 2017

(30) Foreign Application Priority Data
Mar. 27, 2015 (IN) 1581/CHE/2015

(51) Int. Cl. H01L 31/048; H01L 31/049; H01L 31/052; B32B 15/082; B32B 15/18; B32B 15/20; B32B 27/08; B32B 27/30; B32B 27/32; B32B 27/36; C09D 133/06; C09D 5/08

(52) U.S. Cl. CPC H01L 31/0481; B32B 2457/12; H01L 31/052; B32B 15/082; B32B 15/18; B32B 15/20; B32B 27/08; B32B 27/304; B32B 27/306; B32B 27/322; B32B 27/36; C09D 133/06; C09D 5/08; B32B 2255/06; B32B 2255/26; B32B 2264/102; B32B 2264/104; B32B 2270/00; B32B 2307/204; B32B 2307/302; B32B 2307/412; B32B 2307/732; H01L 31/049

(57) ABSTRACT

The present invention relates to dielectric coating formulation for solar module where a separate adhesive layer is not required for applying the formulation to the solar module. Preferably, the solar module is a light weight solar module.

### PRIORITY CLAIM

The present application is a National Phase entry of PCT Application No. PCT/M2016/051669, filed Mar. 24, 2016, which claims priority from IN Patent Application No. 1581/CHE/2015, filed Mar. 27, 2015, each of which is hereby fully incorporated herein by reference.

### FIELD OF INVENTION

The present invention relates to the dielectric coating formulation for use in solar modules, method of manufacture of said formulation for a metal integrated solar module. Preferably, the solar module is a light weight metal integrated solar module.

### BACKGROUND AND PRIOR ART

Solar modules are large-area opto-electronic devices that convert solar radiation directly into electrical energy. They are made by interconnecting individually formed and separate solar cells e.g. multi-crystalline or mono-crystalline silicon solar cells and integrating them into a laminated solar module. The laminated modules generally comprise a front transparent, protective panel and a rear metallic panel referred to as backsheet. The main function of backsheet includes acting as barrier against vapour/moisture, UV resistance, electrical insulation, mechanical support and protection and weathering resistance. Generally, backsheet is metallic in nature and is made up of materials selected from stainless steel, galvanized steel, aluminum sheet, brass, copper and any other material which are having excellent heat conducting properties.

A conventional backsheet includes the following layers deposited thereon including a dielectric layer, adhesive layer, barrier layer, and a weather resistant layer, not necessarily in the same order. Commercially available the dielectric coating formulations comprise a polymeric substance filled with fillers such as ceramic and carboneous material. However, it is seen that these readily available formulations do not adhere to the metallic substrates adequately and requires use of additional layers acting as an adhesive.

Available solar modules are very heavy due to use of glass as the solar panel (i.e. the side facing the sun) which accounts for about 80% of the weight of the module which poses practical challenges during handling of modules on manufacturing floor and during installation.

Hence there is a need to develop a dielectric formulation which uses minimum number of layers. Particularly, there is a need to develop a dielectric formulation which obviates the use of adhesive layer and yet is integrated with the metallic backsheet because of its electrically insulative nature. It is also an object of the present invention to provide for a light weight solar module permitting ease of transportation and installation thus reducing costs associated therewith.

### SUMMARY OF INVENTION

The present invention relates to a dielectric coating formulation for a solar module where a separate adhesive layer is not required for applying the formulation to the solar module. Preferably, the solar module is a light weight solar module. The present invention further relates to a method of making said dielectric coating formulation.

### BRIEF DESCRIPTION OF DRAWINGS

A full understanding of the invention can be gained from the following description of the preferred embodiments when read in conjunction with the accompanying drawings in which—

FIG. 1 and inset FIGS. 1a and 1b illustrate layout of backsheet;

FIGS. 2a and 2b illustrate the preparation for peel test;

FIG. 3 depicts the method for peel test;

FIGS. 4a and 4b illustrate results of peel test for conventional formulation;

FIG. 5 depicts the result of peel test for formulation of present invention;

FIG. 6 shows the solar module layout with solar cells interconnected with copper wire mesh/grid structure;

FIG. 7 depicts the solar module layout with conventional 3-busbar solar cells;

FIG. 8 shows the set up for a Normal Operating Cell Temperature (NOCT) test;

FIG. 9A depicts a dry insulation test set-up;

FIG. 9B depicts modules without insulation tape;

FIG. 9C depicts modules with insulation tape around the edges;

FIG. 10A depicts a module design for 40 W;

FIG. 10B depicts a light weight portable module;

FIG. 10C depicts mounting solutions for frameless modules.

FIG. 11 graphically depicts the adhesion values achieved with a solar module according to an embodiment.

### DETAILED DESCRIPTION

For the purposes of the following detailed description, it is to be understood that the invention may assume various alternative variations and step sequences, except where expressly specified to the contrary. Moreover, other than in any operating examples, or where otherwise indicated, all numbers expressing, for example, quantities of ingredients used in the specification are to be understood as being modified in all instances by the term “about” in which “about” is defined as ±10% of the nominal value.

It is noted that, unless otherwise stated, all percentages given in this specification and appended claims refer to percentages by weight of the total composition.

It must be noted that, as used in this specification and the appended claims, the singular forms “a,” “an” and “the” include plural referents unless the content clearly dictates otherwise.

The terms “preferred” and “preferably” refer to embodiments of the invention that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the invention.

As used herein, the terms “comprising”, “including”, “having”, “containing”, “involving” and the like are to be understood to be open-ended, i.e., to mean including but not limited to.

Unless otherwise defined, all technical and scientific terms used herein have the same meaning as commonly understood by a person skilled in the art to which this invention pertains. In the case of conflict, the present document, including definitions will control.

In one aspect, the present invention discloses a dielectric coating formulation for solar module (10). The formulation comprises of at least two polymers selected from polyacrylamide, acrylics, epoxy, amides, polyurethane, imides, styrene, polystyrene, high density polyethylene, polyethylene terephthalate, their organic monomers, copolymers, modified polymers thereof. The polymers are used in the ratio of 20-60% w/w:20-30% w/w of the formulation.

The formulation further comprises excipients such as at least one each of initiator, cross-linker, chain transfer agent, catalyst, and insulators, additives selected from organic lubricant, aromatic smells, viscosity controller and stabilizers. Initiator is selected from at least one of benzoyl peroxide, azoisobutyronitrile, MEK peroxide, butyl peroxide, methyl orange. The catalyst for polymerization is selected from chain transfer agent such as N-dodecyl mercaptan, thiol-group consisting compounds and halo carbon-group containing compounds. The cross linker is tannic acid. The insulators include at least one of mica, clay, ceramic oxides selected from silica, calcium carbonate, alumina, gerconia and graphene oxide. The insulator material has particle sizes between 10 nm to 100 micron The additives include organic lubricants to reduce coefficient of friction while forming of being of insulating sheets such as wax, sulphur and phosphorous free compounds for example, naphthalate, oleate, octatate, cabonate etc. The aromatic smells are preferably mineral terpentine oil or pine oil. The viscosity controllers are solvent xylene, butanol, isopropanol including thickenening agents such as butyl-, methyl-, ethyl-cellosov. Stabilizers are selected from BYK 378, 389N.

It is to be noted that the polymers used in the dielectric coating formulation have both dielectric and adhesive properties. As a result, the dielectric coating formulation of present invention is directly applied on the metallic backsheet of the solar module. Therefore, unlike in conventional dielectric coating formulation, a separate adhesive layer is not required for application of dielectric coating formulation of present invention to said metallic backsheet.

Modified polymers provide require performance such as adhesion, corrosion resistance, insulation, flexural strength, free of holidays and post-adhesion etc. It is found that the combination of polymers in the present dielectric coating formulation provides excellent adhesion and corrosion performance as compared to individual polymer. The same formulation may be used with one polymer, for example engineered imide class polymers, but the cost is very high as compared to our claimed formulation.

The backsheet being metallic is made up of materials selected from stainless steel, galvanized steel, aluminum sheet, brass, copper and any other material which are having excellent heat conducting properties, the thickness of the metal sheet can range from 0.1 mm to 2 mm. The dielectric coating formulation of the present invention adheres to almost any metal providing flexibility in use.

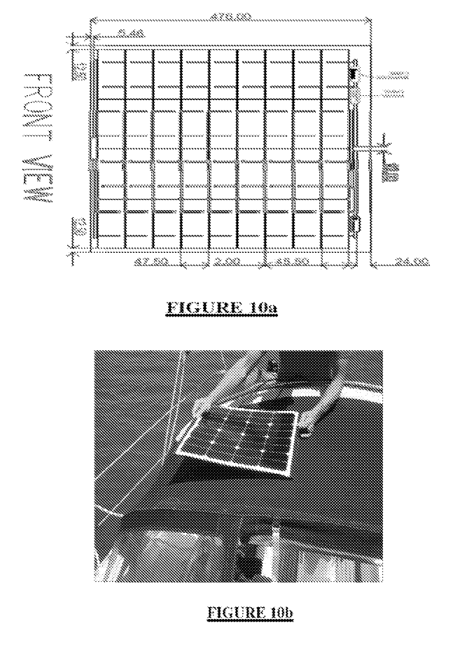

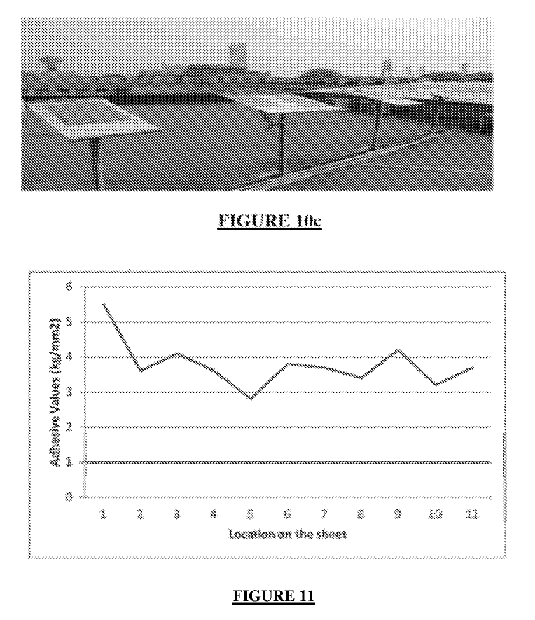

In one aspect depicted in FIG. 10, the present invention provides for a frameless module which does not use any glass. The top side (solar-side) of the module comprises a thin polymeric film (11) whereas the bottom side of the module which attaches to the metallic backsheet (15) is coated with the dielectric coating formulation of the present invention.

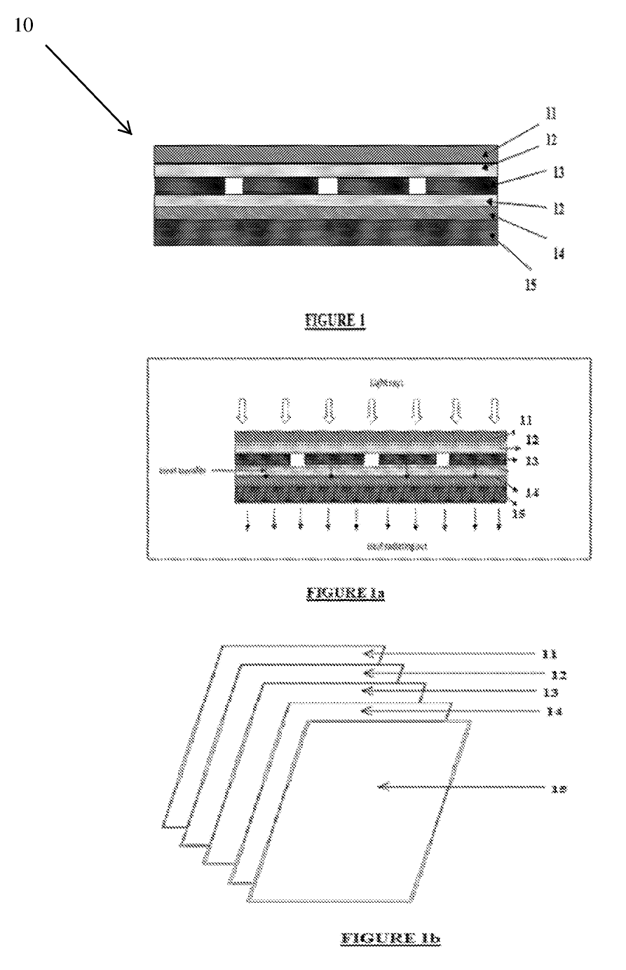

In one embodiment of the present invention, the dielectric coating formulation is adhered to ethyl vinyl acetate (EVA) which is used for laminating solar cells thus hermetically sealing the solar module. In this embodiment, the solar panel of the present invention comprises 5 layers. The dielectric coating formulation of the present invention is applied on metal backsheet (15) followed by ethyl vinyl acetate layer (EVA) (12) laminating the solar cell (13) with the front panel comprising of ethylene tetraflouroethylene (ETFE) layer (11) (refer FIG. 1), ethylene chlorofluoroethylene (ECTFE), perfluoro alkoxy, fluorinated ethylene propylene, poly vinylidene fluoride, tetrafluoroethylene hexafluoropropylene vinylidene fluoride, polyethylene terephthalate (PET), fluoro ethylene propylene, polytetrafluoroethylene, other fluoropolymer materials such as Tefzel and polyvinyl fluoride (PVF), and combination thereof. This formulation clearly does not include an additional adhesion layer as seen in conventional modules. ETFE acts as a front sheet having a transparency of about 93% (similar to glass) and coated galvanized steel sheet acts as the backsheet. (Refer FIG. 1a, 1b).

A method of preparation of said dielectric coating formulation for a solar module comprising the steps of—

a. adding chain transfer agent to organic monomers in presence of initiator causing chain transfer polymerisation;

b. adding insulators in the range of 2-30% by weight of the formulation; additives in the range of about 1-10%.

Further wide applicability can be ensured by equally applying the photovoltaic module of the present invention to areas having severe heat or high temperature and high-humidity tropical weather as well as desert areas.

The following example is provided to better illustrate the claimed invention and is not to be interpreted in any way as limiting the scope of the invention. All specific materials, and methods described below, fall within the scope of the invention. These specific compositions, materials, and methods are not intended to limit the invention, but merely to illustrate specific embodiments falling within the scope of the invention. One skilled in the art may develop equivalent materials, and methods

without the exercise of inventive capacity and without departing from the scope of the invention. It is the intention of the inventors that such variations are included within the scope of the invention.

### Example-1

| Sr. No. | Ingredient | % w/w |
|---|---|---|
| 1 | Styrene Modified Acrylate (30% Solid) | 53 |
| 2 | Imide Modified Methacrylate | 27 |
| 3 | Solvent Xylene | 50 |
| 4 | Dispersant (BYK 378, 389N) | 0.1 |
| 5 | Thickener (butyl cellosov, methyl or ethyl) | 0.5 |
| 6 | Mica + Clay | 3% |
| 7 | Benzoyl Peroxide + Azobisisobutyronitrile | 0.05 |
| 8 | N-Dodecyl Mercaptan | 0.05 to [symbol] |
| 9 | Tannic Acid | 0.05-1% |
| 10 | Organic Lubricants (Wax) | 0.01-2% |
| 11 | Aromatic smell | 0.01-2% |

[symbol]

indicates data missing or illegible when filed

The dielectric coating formulation was subjected to following tests—

1. Peel Test: This test is conducted to see the adhesion strength of the dielectric coating with ethyl vinyl acetate (EVA). The peel test tab is made before lamination and a small piece of smooth release sheet is placed under the outer edge of the tab. The area to be peel tested is prepared by making two parallel cuts completely through the encapsulation system to the superstrate or the substrate (depending

on which bond is being tested) at a position perpendicular to the exposed edge in the area between bus bars.

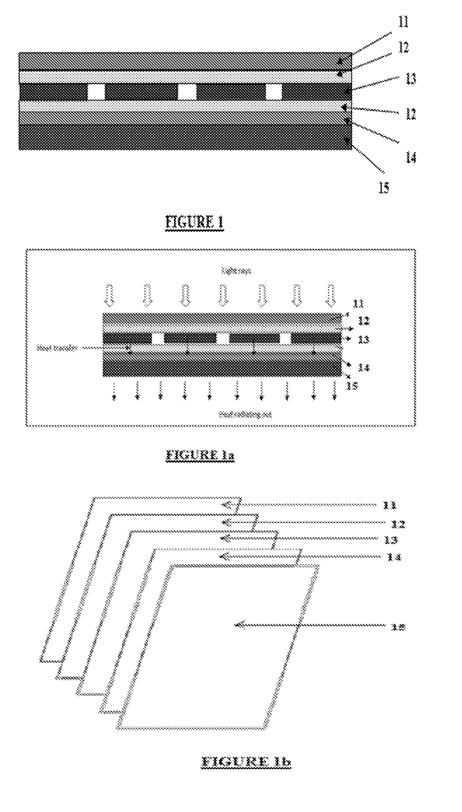

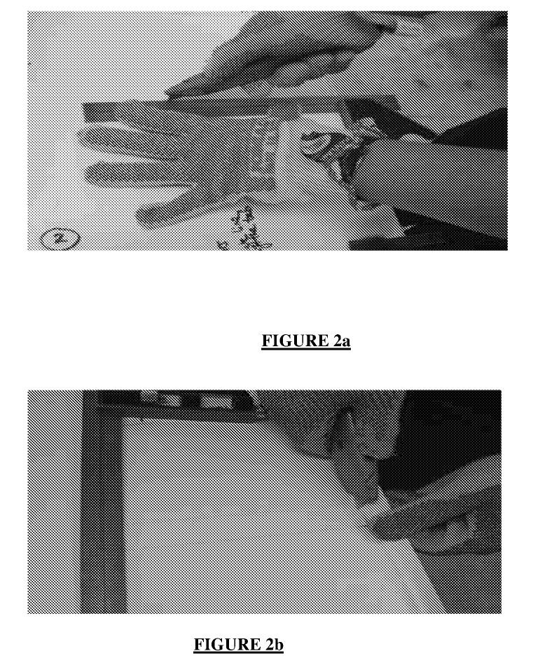

Peel Test Preparation: As seen in FIGS. 2a and 2b, the two parallel cuts are to be located within 12 mm (½) inch of the center and of the exposed edge of the module. The cuts are to be spaced 25 mm (1 inch) apart and should extend to the edge of the cell closest to the module edge. If there are no cells, the cuts should be 25-50 mm (1-2 inches) long. Using a scraping tool, create the tab to be peel tested by separating 6 mm (¼ inch) of the encapsulation system from the superstrate or substrate. If the encapsulant has thinned at the edge of the module, the tab should be of sufficient length to allow the gripper device to grasp the full thickness of the encapsulant to avoid premature tearing of the sample.

Method: As seen in FIG. 3 secure the module onto a flat work surface. Apply power to the force gauge and set it to T PEAK mode. Attach the gripper device to the tab. Zero the force gauge. Pull up on the force gauge at a 90° angle to the dielectric coated metallic backsheet until the encapsulant pulls away from the superstrate/substrate or tears. Do not pull the tab beyond the edge of the cells. Record the peak pull force in kg (or pounds) and failure mode (tears or release).

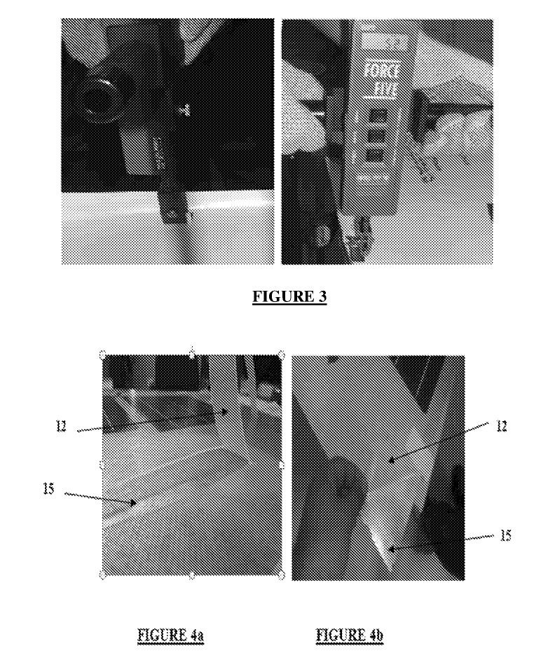

Result: This test was conducted for commercially available formulation as well as the formulation of the present invention. It was noted that there was complete peeling of the EVA from backsheet with the adhesion strength coming around 1.6 kg/inch for commercially available formulation whereas with the formulation of present invention, the adhesion strength was higher at 3.7 kg/inch (refer FIGS. 4a, 4b, 5 and 11).

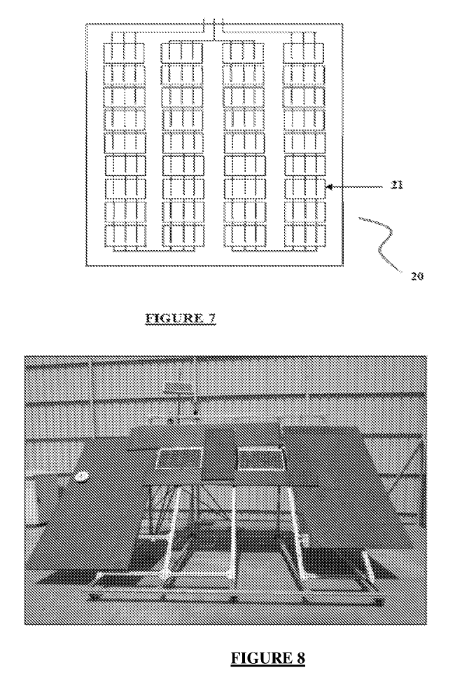

2. Electrical Performance of coated steel backsheet panel at NOCT and STC: The set up for carrying out NOCT test is depicted in FIG. 8. The NOCT (Nominal Operating Cell Temperature) and STC (Standard Operating Condition) test procedure is as per IEC 61215. This test is carried out to determine Nominal Operating cell temperature of the solar panel and the electrical performance of the less same with conventional polymer backsheet module.

| Parameters | NOCT value (° C.) | STC value (° C.) |
|---|---|---|
| Pmax (W) | 26.073 | 40.466 |
| Isc (A) | 1.976 | 2.409 |
| Voc (V) | 19.072 | 22.467 |
| Imp (A) | 1.733 | 2.207 |
| Vmp (V) | 15.025 | 18.336 |
| FF (%) | 69.1 | 74.8 |
| Eft (%) | 9.378 | 11.660 |

3. Dielectric Insulation Withstand Voltage Versus Lamination Cycle:

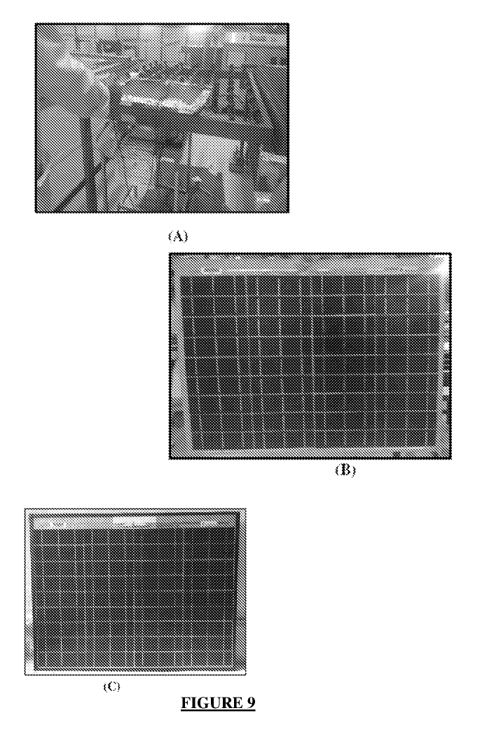

In accordance with FIGS. 9A and 9B, the frameless solar panel of the present invention is insulated using insulation tape around the edges of the laminate and tested for its insulation properties. The set-up is depicted in FIG. 9a. The test procedure is as per IEC 61215. Dry Insulation test is carried out to determine whether or not the module is sufficiently well-insulated between current-carrying parts and the frame or the outside world.

Wet leakage test is done to evaluate the insulation of the module under wet operating conditions and verify that moisture from rain, fog, dew or melted snow does not enter the active parts of the module circuitry, where it might cause corrosion, a ground fault or a safety hazard.

It was concluded that modules with insulation tape around the panels (FIG. 9c) passed the insulation dry test with proper lamination cycle as compared to non-insulated modules (see FIG. 9b). Results are tabulated as follows—

With high cycle time (22 min) & temperature (158° C.), the lamination seems to be proper and hence high Insulation Resistanceof 1 Gohm and high voltage (1500V) withstanding capability of the steel backsheet panels

| | Dry IR | | Dry IR | | Wet IR | | HV | HV |
|---|---|---|---|---|---|---|---|---|
| | (1000 V/ | | (500 V/ | | (1000 V/ | | (1 KV// | (1.5 KV// |
| Serial No. | 2 min) | | 2 min) | | 2 min) | | min) | min) |
| 9F43E25 | >1000 | Mohm | >1000 | Mohm | >1200 | Mohm | Pass | Pass |
| (LAM-158° C. & | | | | | | | (0.996 KV) | (1.49 KV) |
| 22 MIN) | | | | | | | | |
| 9F43E25 | >1000 | Mohm | >1000 | Mohm | >1200 | Mohm | Pass | Failed |
| (LAM-158° C. & | | | | | | | (0.996 KV) | (0.996 KV) |
| 16 MIN) | | | | | | | | |
| 9F51B 8D | >1000 | Mohm | >1000 | Mohm | >1200 | Mohm | Pass | Failed |
| (LAM-158° C. & | | | | | | | (0.996 KV) | (0.996 KV) |
| 16 MIN) | | | | | | | | |
| 9F51B73 | >1000 | Mohm | >1000 | Mohm | >1500 | Mohm | Pass | Failed |
| (LAM-158° C. & | | | | | | | (0.996 KV) | (0.996 KV) |
| 16 MIN) | | | | | | | | |
| 9FB9E2F | 0 | Mohm | 0 | Mohm | 0 | Mohm | Fail | Failed |

| | | |
|---|---|---|
| (LAM-158° C. & | (0.469 KV, | (0.563 KV, |
| 12 MIN | 0.068 mA, | 0.081 mA, |
| | 3.5 S) | 2.7 s) |

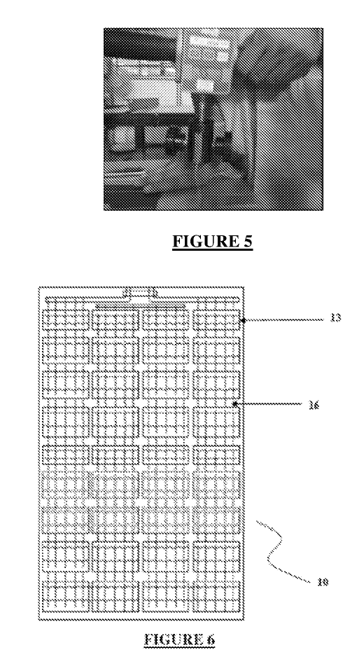

With the lamination cycle of 158° C. and 22 min, the laminate can sustain 1500V for 1 min. It gives both dry and wet IR value of more than 1 Gohm. It clearly shows with higher lamination cycle the dielectric withstand capacity of the laminates increases. In another embodiment of the present invention seen in FIG. 6, the formulation was employed in a solar module (10) comprising multiple solar cells (13) interconnected with copper wire mesh/grid (16). In yet another embodiment seen in FIG. 7, the formulation was employed in solar module (20) comprising conventional solar cells (21) having 3 bus-bars.

FIG. 10a depicts a module design of 40 W. These modules can be used on the roof tops of huts/kutcha houses-urban slums and majority of rural houses, rooftop of toilets and also on the roof of the houses for power generation. These modules can also be used in areas having severe heat or high temperature and high humidity tropical weather as well as desert areas as well as on train platform roofs and stadium roofs.

Since the modules of the present invention are frameless in which the frames have been replaced with insulating tape sealed around the edges, they can be simply clamped over the roof using conventional clamping methods (see FIG. 10c).

Advantageously, the dielectric coating formulation of the present invention when used on metal backsheet provides better adhesion and electrical insulation. The frameless light weight module is easier to handle at the manufacturing floor as well as during transportation and handling. Because the modules have a low profile and are light, nearly 3 times the number of modules can be fitted in a standard 40 ft. container as compared to traditional modules. The shipping costs and installation labour reduces drastically.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the invention which is to be given the full breadth of the appended claims and any and all equivalents thereof.

1. A dielectric coating formulation for a solar module, the dielectric formulation comprising:
a. at least two polymers selected from the group consisting of polyacrylamides, acrylics, epoxies, amides, polyurethanes, imides, styrenes, polystyrenes, high density polyethylenes, polyethylene terephthalates, their organic monomers, copolymers, and modified polymers thereof;
b. excipients including at least one each of an initiator, a cross-linker, a chain transfer agent, a catalyst, one or more insulators, and an additive selected from an organic lubricant, an aromatic smell, a viscosity controller, and a stabilizer;
wherein the dielectric coating has dielectric and adhesive properties.

2. The dielectric coating formulation of claim 1 wherein the dielectric coating formulation is configured to be applied upon an inner surface of a metallic backsheet without any intervening adhesive layer.

3. The dielectric coating formulation of claim 1 wherein a ratio of the at least two polymers is 20-60% w/w:20-30% w/w of the composition thereof.

4. The dielectric coating formulation of claim 1 wherein an adhesion strength of the dielectric formulation is at least 2.7 kg/inch.

5. The dielectric coating formulation of claim 1 wherein the initiator is selected from the group consisting of benzoyl peroxide, azoisobutyronitrile, methyl ethyl ketone (MEK) peroxide, butyl peroxide, and methyl orange.

6. The dielectric coating formulation of claim 1 wherein the catalyst is a chain transfer agent selected from the group consisting of N-dodecyl mercaptan, thiol-group containing compounds, and halo carbon group containing compounds.

7. The dielectric coating formulation of claim 1 wherein the cross-linker is a tannic acid.

8. The dielectric coating formulation of claim 1 wherein the one or more insulators include at least one of mica, clay, and ceramic oxides selected from the group consisting of silica, calcium carbonate, alumina, gerconia, and graphene oxide.

9. The dielectric coating formulation of claim 1 wherein the at least two polymers are styrene modified acrylate (30% solid) and imide modified methacrylate, and the at least two polymers are present in the dielectric coating formulation in a ratio of 53:27% w/w.

10. The dielectric coating formulation of claim 1 wherein said solar module is a light weight solar module.

11. A light weight solar module comprising sequentially laminated layers of—
a. a polymeric film layer on its a front side of the light weight solar module;
b. an ethyl vinyl acetate (EVA) film layer immediately adjoining at least one solar cell; and
c. metallic back sheet coated with a dielectric coating adjacent to the EVA film layer, the dielectric coating comprising:
at least two polymers selected from the group consisting of polyacrylamides, acrylics, epoxies, amides, polyurethanes, imides, styrenes, polystyrenes, high density polyethylenes, polyethylene terephthalates, their organic monomers, copolymers, and modified polymers thereof;
excipients including at least one each of an initiator, a cross-linker, a chain transfer agent, a catalyst, one or more insulators, and an additive selected from an organic lubricant, an aromatic smell, a viscosity controller, and a stabilizer;
wherein the dielectric coating has dielectric and adhesive properties.

12. The light weight solar module of claim 11 wherein the polymeric film comprises at least one of the group consisting of an ethylene tetrafluoroethylene (ETFE), a perfluoroalkoxy, a fluorinated ethylene propylene, a polyvinylidene fluoride, a tetrafluoroethylenehexafluoropropylenevinylidene fluoride, a polyethylene terephthalate (PET), a fluoro ethylene propylene, a polytetrafluoroethylene, and a fluoropolymer materials.

13. The light weight solar module of claim 11, wherein the metallic back sheet comprises a metal selected from the group consisting of at least one of galvanized steel, an aluminum, a copper, a brass, a sheet steel, and a stainless steel, and wherein the metallic back sheet has a thickness of between about 0.1 mm and about 2 mm.

14. A method of preparation of said dielectric coating formulation for a solar module comprising the steps of:
combining at least two polymers selected from the group consisting of polyacrylamides, acrylics, epoxies, amides, polyurethanes, imides, styrenes, polystyrenes, high density polyethylenes, polyethylene terephthalates, their organic monomers, copolymers, and modified polymers thereof, and wherein at least one of the at least two polymers comprises organic monomers;
adding excipients including at least one each of a cross-linker, a catalyst, and an additive selected from an organic lubricant, an aromatic smell, a viscosity controller, and a stabilizer to the combination of the at least two polymers to form a dielectric coating formulation that has both dielectric and adhesive properties;
adding a chain transfer agent to the organic monomers in the presence of an initiator to cause a chain transfer polymerization;
adding one or more insulators in the range of 2-30% w/w of the formulation;
wherein the total amount of excipients, chain transfer agent, and insulators is between about 1% and about 10% w/w.
